(19) United States
(12) Patent Application Publication
(10) Pub. No.: US 2025/0172394 A1
(43) Pub. Date: May 29, 2025

(54) ELECTRONIC DEVICE FOR LOCATION DETECTION, AND METHOD FOR OPERATING SAME

(71) Applicant: Samsung Electronics Co., Ltd., Suwon-si (KR)

(72) Inventors: Junyoung WOO, Suwon-si (KR); Chaeman Lim, Suwon-si (KR)

(73) Assignee: Samsung Electronics Co., Ltd., Suwon-si (KR)

(21) Appl. No.: 19/040,265

(22) Filed: Jan. 29, 2025

Related U.S. Application Data
(63) Continuation of application No. PCT/KR2023/012810, filed on Aug. 29, 2023.

(30) Foreign Application Priority Data
Oct. 11, 2022 (KR) 10-2022-0129509
Oct. 25, 2022 (KR) 10-2022-0138680

(51) Int. Cl. G01C 21/08; G01C 21/20; G01R 33/02

(52) U.S. Cl. CPC G01C 21/08; G01R 33/0206; G01C 21/206

(57) ABSTRACT

An electronic device includes: a sensor; at a memory storing instructions; and at least one processor operatively connected to the sensor, where, by executing the instructions, the at least one processor is configured to: obtain information about a first magnetic field of a virtual marker through the sensor; configure a reference distance, based on the information about the first magnetic field of the virtual marker; obtain information about a second magnetic field corresponding to a location of the electronic device, based on a specified detection time interval; and detect a Euclidean distance, based on the information about the first magnetic field of the virtual marker and the information about the second magnetic field corresponding to the location of the electronic device.

### CROSS-REFERENCE TO RELATED APPLICATIONS

This application is a continuation of International Application No. PCT/KR2023/012810, filed on Aug. 29, 2023, in the Korean Intellectual Property Receiving Office, which is based on and claims priority to Korean Patent Applications No. 10-2022-0138680, filed on Oct. 25, 2022 and No. 10-2022-0129509, filed on Oct. 11, 2022, in the Korean Intellectual Property Office, the disclosures of which are incorporated by reference herein in their entireties.

### BACKGROUND

### 1. Field

This disclosure relates to a device and a method for location detection in an electronic device.

### 2. Description of Related Art

An electronic device may detect the location of the electronic device in an indoor space by using magnetic field information (or Earth's magnetic field) having a different characteristic at each location due to the influence of external environmental factors, such as a steel structure, in the indoor space. For example, the electronic device may configure a specific location as a virtual marker, based on magnetic field information measured at the specific location in the indoor space. The electronic device may identify whether the electronic device reaches the specific location configured as the virtual marker by comparing magnetic field information measured at the location of the electronic device with the magnetic field information at the specific location configured as the virtual marker.

The electronic device may perform an operation of comparison between the magnetic field information about the location of the electronic device and the magnetic field information about the specific location configured as the virtual marker according to a specified period (e.g., about 100 ms) to identify whether the electronic device reaches the specific location configured as the virtual marker. For example, the operation of comparison between the pieces of magnetic field information may include at least one of an operation of compensating for a change in the waveform of a signal according to the moving speed of the electronic device (e.g., a dynamic time warping (DTW) operation) or an operation of determining whether the magnetic field information about the location of the electronic device and the magnetic field information about the specific location configured as the virtual marker are similar (e.g., a correlation operation, a DTW operation, a histogram operation, a range operation, an angle operation, or a bias operation). The electronic device may increase the load of a processor and power consumption due to the operation of comparison between the magnetic field information about the location of the electronic device and the magnetic field information about the specific location configured as the virtual marker based on the specified period.

### SUMMARY

Provided are a device and a method for reducing complexity in an electronic device detecting the location of the electronic device, based on magnetic field information.

Additional aspects will be set forth in part in the description which follows and, in part, will be apparent from the description, or may be learned by practice of the presented embodiments.

According to an aspect of the disclosure, an electronic device may include: a sensor; at least one memory storing instructions; and at least one processor operatively connected to the sensor, where, by executing the instructions, the at least one processor is configured to: obtain information about a first magnetic field of a virtual marker through the sensor; configure a reference distance, based on the information about the first magnetic field of the virtual marker; obtain information about a second magnetic field corresponding to a location of the electronic device, based on a specified detection time interval; detect a Euclidean distance, based on the information about the first magnetic field of the virtual marker and the information about the second magnetic field corresponding to the location of the electronic device; restrict an operation of comparing the information about the first magnetic field and the information about the second magnetic field in a state in which the Euclidean distance does not satisfy a specified detection condition based on the reference distance; and perform the operation of comparing the information about the first magnetic field and the information about the second magnetic field in a state in which the Euclidean distance satisfies the specified detection condition based on the reference distance.

The at least one processor may be further configured to obtain information about a magnetic field in three axes related to at least a portion of a real space configured as the virtual marker through the sensor.

The at least one processor may be further configured to: detect a range of the first magnetic field and a slope of the first magnetic field; and select one of a plurality of specified reference distances having different distances, based on the range of the first magnetic field and the slope of the first magnetic field.

The at least one processor may be further configured to: detect a change rate of the slope of the first magnetic field, based on the range of the first magnetic field and the slope of the first magnetic field; select a shortest reference distance among the plurality of reference distances in a state in which the change rate of the slope of the first magnetic field satisfies a specified linear condition; and select a longest reference distance among the plurality of reference distances in a state in which the change rate of the slope of the first magnetic field does not satisfy the specified linear condition.

The at least one processor may be further configured to detect the Euclidean distance between the virtual marker and the location of the electronic device, based on a difference in strength between a magnetic field in each of three axes related to the virtual marker and a magnetic field in each of the three axes corresponding to the location of the electronic device.

The at least one processor may be further configured to: restrict the operation of comparing the information about the first magnetic field and the information about the second magnetic field in a state in which the Euclidean distance exceeds the reference distance; and perform the operation comparing the information about the first magnetic field and the information about the second magnetic field in a state in which the Euclidean distance is less than or equal to the reference distance.

One or more memories among the at least one memory may be configured to store information related to at least one of a location of a real space configured as the virtual marker, the information about the first magnetic field obtained through the sensor, or a function related to the virtual marker.

The at least one processor may be further configured to automatically execute a function related to the virtual marker stored in the at least one memory based on determining that the electronic device reaches the virtual marker through the operation of comparing.

According to an aspect of the disclosure, provided is an operating method of an electronic device, the method may include: obtaining information about a first magnetic field of a virtual marker through a sensor of the electronic device; configuring a reference distance, based on the information about the first magnetic field of the virtual marker; obtaining information about a second magnetic field corresponding to a location of the electronic device, based on a specified detection time interval; detecting a Euclidean distance, based on the information about the first magnetic field of the virtual marker and the information about the second magnetic field corresponding to the location of the electronic device; restricting an operation of comparing the information about the first magnetic field and the information about the second magnetic field in a state in which the Euclidean distance does not satisfy a specified detection condition based on the reference distance; and performing the operation of comparing the information about the first magnetic field and the information about the second magnetic field in a state in which the Euclidean distance satisfies the specified detection condition based on the reference distance.

The configuring the reference distance may include: detecting a range of the first magnetic field and a slope of the first magnetic field; and selecting one of a plurality of specified reference distances having different distances, based on the range of the first magnetic field and the slope of the first magnetic field.

The selecting the reference distance may include: detecting a change rate of the slope of the first magnetic field, based on the range of the first magnetic field and the slope of the first magnetic field; selecting a shortest reference distance among the plurality of reference distances in a state in which the change rate of the slope of the first magnetic field satisfies a specified linear condition; and selecting a longest reference distance among the plurality of reference distances in a state in which the change rate of the slope of the first magnetic field does not satisfy the specified linear condition.

The detecting the Euclidean distance may include detecting the Euclidean distance between the virtual marker and the location of the electronic device, based on a difference in strength between a magnetic field in each of three axes related to the virtual marker and a magnetic field in each of the three axes corresponding to the location of the electronic device.

The restricting the operation of comparing may include restricting the operation of comparing the information about the first magnetic field and the information about the second magnetic field in a state in which the Euclidean distance exceeds the reference distance.

The performing the operation of comparing may include performing the operation of comparing the information about the first magnetic field and the information about the second magnetic field in a state in which the Euclidean distance is less than or equal to the reference distance.

The method may further include automatically executing a function related to the virtual marker based on determining that the electronic device reaches the virtual marker through the operation of comparing.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a block diagram of an electronic device according to an embodiment of the disclosure;

FIG. 2 is a block diagram of an electronic device for location detection of the electronic device based on a virtual marker according to an embodiment;

FIG. 3 is a flowchart illustrating that an electronic device detects the location of the electronic device, based on a virtual marker according to an embodiment;

FIG. 4 illustrates an example in which an electronic device detects the location of the electronic device, based on a virtual marker according to an embodiment;

FIG. 5 is a graph illustrating the relationship between a Euclidean distance and the location of an electronic device based on a virtual marker in the electronic device according to an embodiment;

FIG. 6 is a flowchart illustrating that an electronic device configures a reference distance related to a Euclidean distance according to an embodiment;

FIG. 7A illustrates an example of magnetic field information related to a virtual marker in an electronic device according to an embodiment;

FIG. 7B illustrates an example of a Euclidean distance based on a virtual marker in an electronic device according to an embodiment;

FIG. 8A illustrates an example of magnetic field information related to a virtual marker in an electronic device according to an embodiment; and

FIG. 8B illustrates an example of a Euclidean distance based on a virtual marker in an electronic device according to an embodiment.

### DETAILED DESCRIPTION

Hereinafter, embodiments will be described in detail with reference to the accompanying drawings.

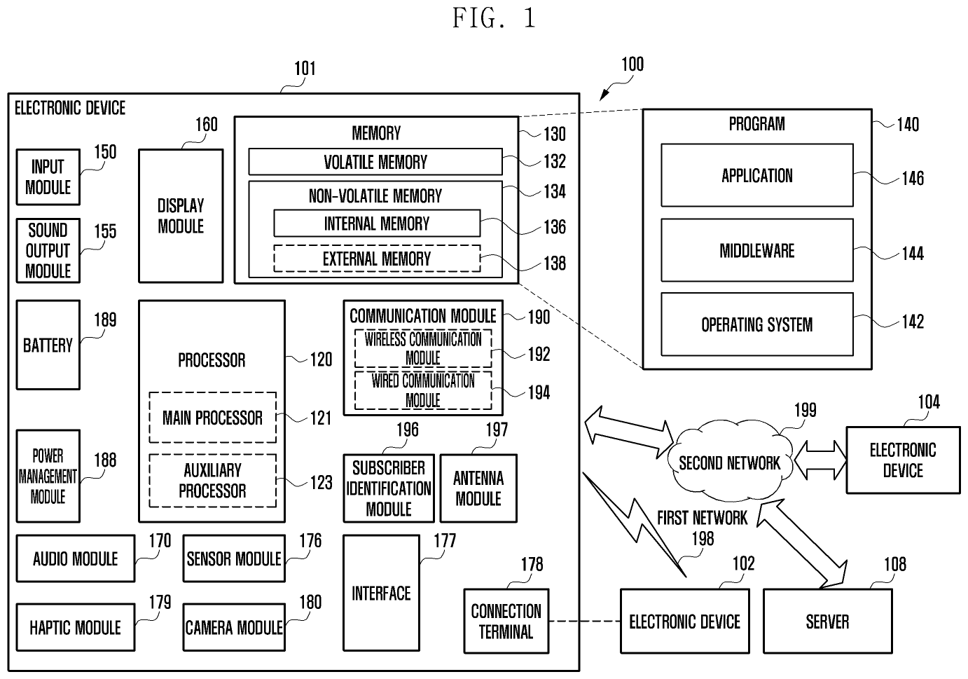

FIG. 1 is a block diagram illustrating an example electronic device 101 in a network environment 100 according to various embodiments. Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC. According to an embodiment, the subscriber identification module 196 may include a plurality of subscriber identification modules. For example, the plurality of subscriber identification modules may store different subscriber information.

The antenna module 197 may transmit or receive a signal or power to or from the outside (e.g., the external electronic device) of the electronic device 101. According to an embodiment, the antenna module 197 may include an antenna including a radiating element including a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to various embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band. For example, the plurality of antennas may include a patch array antenna and/or a dipole array antenna.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

The electronic device according to various embodiments may be one of various types of electronic devices. The electronic devices may include, for example, a portable communication device (e.g., a smartphone), a computer device, a portable multimedia device, a portable medical device, a camera, a wearable device, a home appliance, or the like. According to an embodiment of the disclosure, the electronic devices are not limited to those described above.

It should be appreciated that various embodiments of the present disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), the element may be coupled with the other element directly (e.g., wiredly), wirelessly, or via a third element.

As used in connection with various embodiments of the disclosure, the term “module” may include a unit implemented in hardware, software, or firmware, or any combination thereof, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the “non-transitory” storage medium is a tangible device, and may not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

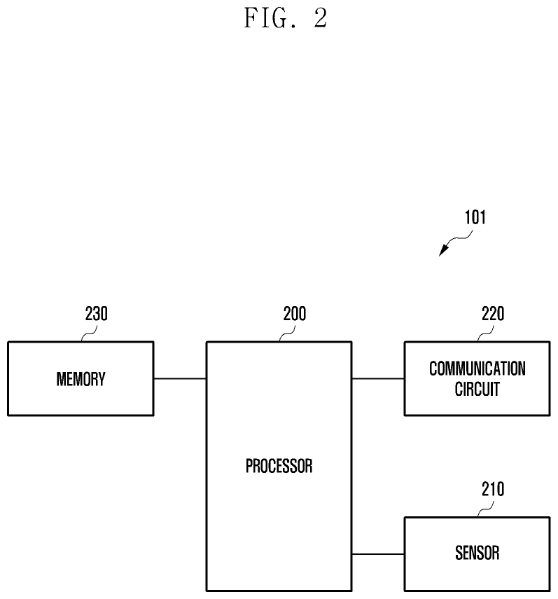

FIG. 2 is a block diagram of an electronic device for location detection of the electronic device based on a virtual marker according to an embodiment. According to an embodiment, the electronic device 101 of FIG. 2 may be at least partly similar to the electronic device 101 of FIG. 1, or may include other embodiments of an electronic device.

According to an embodiment referring to FIG. 2, the electronic device 101 may include at least one of a processor (e.g., including processing circuitry) 200, a sensor 210, a communication circuit (or communication circuitry) 220, or a memory 230. According to an embodiment, the processor 200 may be substantially the same as the processor 120 of FIG. 1 (e.g., a communication processor), or may be included in the processor 120. The sensor 210 may be substantially the same as the sensor module 176 of FIG. 1, or may be included in the sensor module 176. The communication circuit 220 may be substantially the same as the wireless communication module 192 of FIG. 1, or may be included in the wireless communication module 192. The memory 230 may be substantially the same as the memory 130 of FIG. 1, or may be included in the memory 130. According to an embodiment, the processor 200 may be operatively, functionally, or electrically connected to the sensor 210, the communication circuit 220, or the memory 230.

In an embodiment, the processor 200 may configure a specific location in a real space as a virtual marker. According to an embodiment, the processor 200 may identify the location to be configured as the virtual marker, based on occurrence of an event related to the virtual marker. The processor 200 may control the sensor 210 to obtain magnetic field information about the location to be configured as the virtual marker. The processor 200 may store, in the memory 240, the location of the real space configured as the virtual marker, the magnetic field information about the location configured as the virtual marker obtained through the sensor 210, and information related to a function related to the virtual marker. For example, the magnetic field information about the location configured as the virtual marker is the strength of Earth's magnetic field (or a geomagnetic value) detected through the sensor 210 in an area of a specified size based on the location configured as the virtual marker in the real space, and may include the strength of an x-axis magnetic field (or geometric value), the strength of a y-axis magnetic field, and the strength of a z-axis magnetic field obtained at the same time through the sensor 210. For example, the event related to the virtual marker may occur based on at least one of execution of an application program, execution of a function, reception of a user input, or reception of a communication signal related to the virtual marker. For example, the function related to the virtual marker may include a function that is automatically executed based on the electronic device 101 being determined as having reached the location configured as the virtual marker.

According to an embodiment, the processor 200 may configure a reference distance related to a Euclidean distance, based on the magnetic field information about the virtual marker. According to an embodiment, the processor 200 may select at least one of a plurality of reference distances, based on a change in the slope (or slope change rate) of the x-axis magnetic field, the y-axis magnetic field, and the z-axis magnetic field of the virtual marker. For example, when determining that the change in the slope of the x-axis magnetic field, the y-axis magnetic field, and the z-axis magnetic field of the virtual marker is relatively constant, the processor 200 may select a relatively short reference distance among the plurality of reference distances. For example, a state in which the change in the slope (or slope strength change) is constant may include a state in which the change in the slope (or slope change rate) of the x-axis magnetic field, the y-axis magnetic field, and the z-axis magnetic field is linear (or satisfies a specified linear condition). For example, when determining that the change in the slope of the x-axis magnetic field, the y-axis magnetic field, and the z-axis magnetic field of the virtual mark is not relatively constant, the processor 200 may select a relatively long reference distance among the plurality of reference distances. For example, a state in which the change in the slope (or slope strength change) is not constant may include a state in which the change in the slope (or slope change rate) of the x-axis magnetic field, the y-axis magnetic field, and the z-axis magnetic field is nonlinear (or does not satisfy the specified linear condition). For example, the slopes of the magnetic fields may be detected based on the range of a magnetic field value (or magnetic field strength) of each axis of the virtual mark and the slope of the magnetic field value (or magnetic field strength) of each axis. For example, the range of the magnetic field value (or magnetic field strength) may include a range between the minimum strength value and the maximum strength value of the magnetic field in each axis of the virtual mark. For example, the reference distance related to the Euclidean distance may include a reference distance configured to determine whether to perform a comparison operation for determining whether the electronic device 101 reaches the location (or area) configured as the virtual mark.

According to an embodiment, the processor 200 may detect the Euclidean distance between the location of the electronic device 101 and the virtual marker, based on a specified period (or a specified detection time interval). According to an embodiment, when the specified period (or the specified detection time interval) (e.g., about 100 ms) arrives, the processor 200 may control the sensor 210 to obtain magnetic field information about the location of the electronic device 101. The processor 200 may detect the Euclidean distance, based on the magnetic field information about the location of the electronic device 101 obtained through the sensor 210 and the magnetic field information about the virtual marker. For example, the Euclidean distance is the shortest straight-line distance between the location of the electronic device 101 and the location configured as the virtual marker, and may be calculated based on Equation 1 below.

$$Euclidean distance = {{\sum }_{i = 0}}^{2} {\sum }_{n = 0}^{M - 1} {( {p}_{n , i} - {q}_{n , i} )}^{2} \qquad [ Equation 1 ]$$

For example, i may denote the index of each axis (e.g., x-axis, y-axis, or z-axis) of the magnetic fields, n may denote the index of a vector included in the area of the specified size related to the virtual mark, p_{n,i} may denote the magnetic field value (or magnetic field strength) of an n-th vector of an i-th axis of the virtual mark, and q_{n,i} may denote the magnetic field value (or magnetic field strength) of an n-th vector of an i-th axis of the location of an electronic device 101.

According to an embodiment, the processor 200 may determine whether to perform the comparison operation for determining whether the electronic device 101 reaches the location (or area) configured as the virtual mark, based on the Euclidean distance between the location of the electronic device 101 and the virtual mark. According to an embodiment, when the Euclidean distance between the location of the electronic device 101 and the virtual marker exceeds the reference distance configured based on the magnetic field information about the virtual marker, the processor 200 may determine that the probability that the location of the electronic device 101 reaches the location configured as the virtual marker is relatively low. The processor 200 may restrict performance of the comparison operation for determining whether the electronic device 101 reaches the location (or area) configured as the virtual marker, based on determining that the probability that the location of the electronic device 101 reaches the location configured as the virtual marker is relatively low. According to an embodiment, when the Euclidean distance between the location of the electronic device 101 and the virtual marker is less than or equal to the reference distance configured based on the magnetic field information about the virtual marker, the processor 200 may determine that the probability that the location of the electronic device 101 reaches the location configured as the virtual marker is relatively high. The processor 200 may determine to perform the comparison operation for determining whether the electronic device 101 reaches the location (or area) configured as the virtual marker, based on determining that the probability that the location of the electronic device 101 reaches the location configured as the virtual marker is relatively high.

According to an embodiment, when determining that the comparison operation for determining whether the electronic device 101 reaches the location (or area) configured as the virtual marker, the processor 200 may perform a comparison operation between the magnetic field information corresponding to the location of the electronic device 101 and the magnetic field information about the virtual marker. For example, the comparison operation between the pieces of magnetic field information may include at least one of an operation of compensating for a change in the waveform of a signal according to the moving speed of the electronic device (e.g., a dynamic time warping (DTW) operation) or an operation of determining whether the magnetic field information about the location of the electronic device and the magnetic field information about the specific location configured as the virtual marker are similar (e.g., a correlation operation, a DTW operation, a histogram operation, a range operation, an angle operation, or a bias operation).

According to an embodiment, when determining that the electronic device 101 has reached the location (or area) configured as the virtual mark, based on the comparison operation, the processor 200 may perform the function related to the virtual mark.

According to an embodiment, the sensor 210 is a sensor that measures the magnetic force (geomagnetism) of the Earth, and may include a three-axis geomagnetic sensor capable of measuring the magnetic field value (or the strength of a magnetic field) on each of the x-axis, the y-axis, and the z-axis. According to an embodiment, the sensor 210 may include various types of sensors, such as at least one of a Hall sensor, a magneto-resistance (MR) sensor, or a magneto-impedance (MI) sensor.

According to an embodiment, the communication circuit 220 may support transmitting or receiving at least one of a signal or data to or from at least one external electronic device (e.g., the electronic device 102 or 104 or the server 108 of FIG. 1).

According to an embodiment, the memory 230 may store various data used by at least one component (e.g., the processor 200, the sensor 210, or the communication circuit 220) of the electronic device 101. For example, the data may include at least one of information related to the location in the real space configured as the virtual marker, the magnetic field information about the location configured as the virtual marker obtained through the sensor 210, or information related to the function related to the virtual marker or related to the plurality of reference distances. According to an embodiment, the memory 230 may store various instructions executable through the processor 200.

According to an embodiment, the electronic device 101 may determine whether to perform the comparison operation for determining whether the electronic device 101 reaches the location (or area) configured as the virtual marker, based on the dot product of the magnetic field information about the location of the electronic device 101 and the magnetic field information about the virtual marker. According to an embodiment, when the dot product of the magnetic field information about the location of the electronic device 101 and the magnetic field information about the virtual marker exceeds a specified reference dot product, the processor 200 may restrict the performance of the comparison operation for determining whether the electronic device 101 reaches the location (or area) configured as the virtual marker. According to an embodiment, when the dot product of the magnetic field information about the location of the electronic device 101 and the magnetic field information about the virtual marker is less than or equal to the specified reference dot product, the processor 200 may determine to perform the comparison operation for determining whether the electronic device 101 reaches the location (or area) configured as the virtual marker.

According to an embodiment, an electronic device (e.g., the electronic device 101 of FIG. 1 or FIG. 2) may include a sensor (e.g., the sensor module 176 of FIG. 1 or the sensor 210 of FIG. 2) and a processor (e.g., the processor 120 of FIG. 1 or the processor 200 of FIG. 2) operatively connected to the sensor. According to an embodiment, the processor may obtain information about a first magnetic field of a virtual marker through the sensor. According to an embodiment, the processor may configure a reference distance, based on the information about the first magnetic field of the virtual marker. According to an embodiment, the processor may obtain information about a second magnetic field corresponding to a location of the electronic device, based on a specified period (or specified detection time interval). According to an embodiment, the processor may detect a Euclidean distance, based on the information about the first magnetic field of the virtual marker and the information about the second magnetic field corresponding to the location of the electronic device. According to an embodiment, the processor may restrict an operation of comparison between the information about the first magnetic field and the information about the second magnetic field when the Euclidean distance based on the information about the first magnetic field of the virtual marker and the information about the second magnetic field corresponding to the location of the electronic device does not satisfy a specified detection condition based on the reference distance. According to an embodiment, the processor may perform the operation of comparison between the information about the first magnetic field and the information about the second magnetic field when the Euclidean distance based on the information about the first magnetic field of the virtual marker and the information about the second magnetic field corresponding to the location of the electronic device satisfies the specified detection condition based on the reference distance.

According to an embodiment, the processor may obtain information about magnetic fields of three axes related to at least a portion of a real space configured as the virtual marker through the sensor (e.g., the sensor 210 of FIG. 2).

According to an embodiment, the processor may detect a range of the first magnetic field of the virtual marker and a slope of the first magnetic field; and may select one of a plurality of specified reference distances having different distances, based on the range of the first magnetic field and the slope of the first magnetic field.

According to an embodiment, the processor may detect a change rate of the slope of the first magnetic field, based on the range of the first magnetic field of the virtual marker and the slope of the first magnetic field, may select one relatively short reference distance (e.g., reference distance 2 in Table 1) among the plurality of reference distances when the change rate of the slope of the first magnetic field satisfies a specified linear condition, and may select another relatively long reference distance among the plurality of reference distances when the change rate of the slope of the first magnetic field does not satisfy the specified linear condition.

According to an embodiment, the processor may detect the Euclidean distance between the virtual marker and the location of the electronic device, based on a difference in strength between a magnetic field of each of the three axes related to the virtual marker and a magnetic field of each of the three axes corresponding to the location of the electronic device.

According to an embodiment, the processor may restrict the operation of comparison between the information about the first magnetic field and the information about the second magnetic field when the Euclidean distance between the virtual marker and the electronic device exceeds the reference distance, and may perform the operation of comparison between the information about the first magnetic field and the information about the second magnetic field when the Euclidean distance is less than or equal to the reference distance.

According to an embodiment, the operation of comparison between the first magnetic field of the virtual marker and the second magnetic field of the location of the electronic device may include at least one of a dynamic time warping (DTW) operation, a correlation operation, a histogram operation, a range operation, an angle operation, or a bias operation.

According to an embodiment, a memory may store information related to at least one of a location of a real space configured as the virtual marker, the information about the first magnetic field obtained through the sensor, or a function related to the virtual marker.

According to an embodiment, the processor may automatically execute the function related to the virtual marker when determining that the electronic device reaches the virtual marker through the operation of comparison between the first magnetic field of the virtual marker and the second magnetic field of the location of the electronic device.

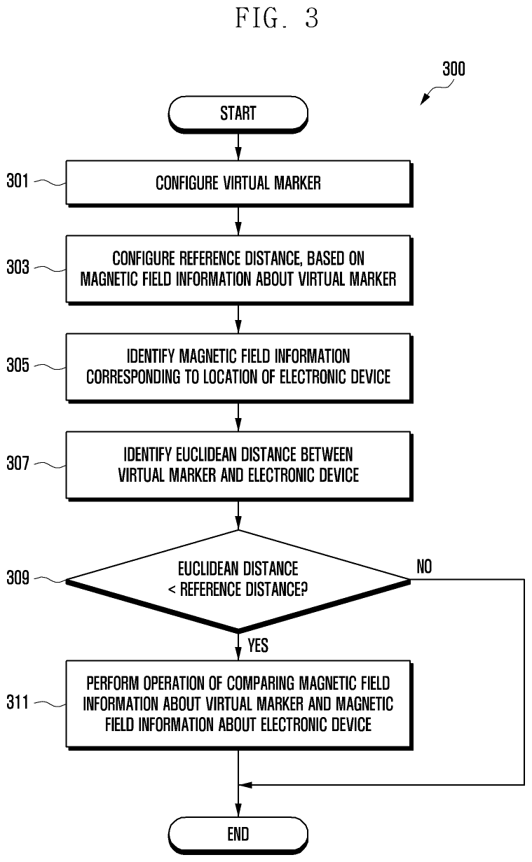

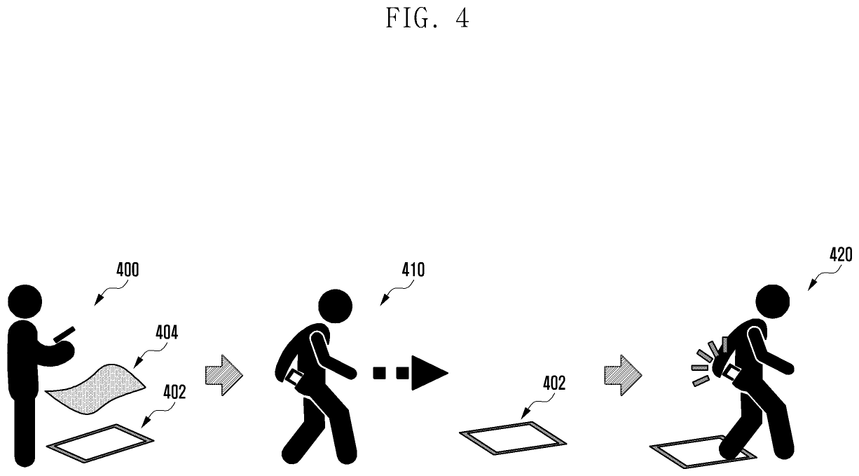

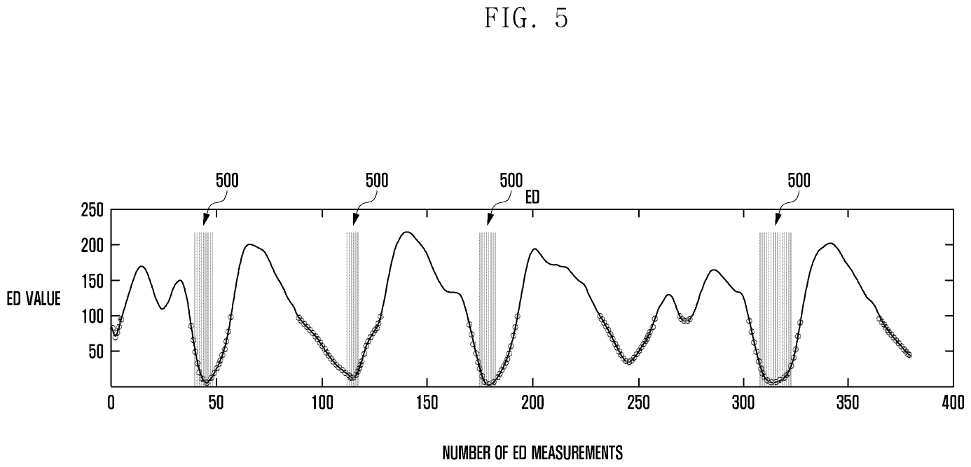

FIG. 3 is a flowchart 300 illustrating that an electronic device detects the location of the electronic device, based on a virtual marker according to an embodiment. In the following embodiments, operations may be sequentially performed, but are not necessarily performed sequentially. For example, the operations may be performed in a different order, or at least two operations may be performed in parallel. For example, the electronic device of FIG. 3 may be the electronic device 101 of FIG. 1 or FIG. 2. At least part of FIG. 3 may be described with reference to FIG. 4 and FIG. 5. FIG. 4 illustrates an example in which an electronic device detects the location of the electronic device, based on a virtual marker according to an embodiment. FIG. 5 is a graph illustrating the relationship between a Euclidean distance and the location of an electronic device based on a virtual marker in the electronic device according to an embodiment.

According to an embodiment of the disclosure with reference to FIG. 3, FIG. 4, and FIG. 5, in operation 301, the electronic device (e.g., the processor 120 of FIG. 1 or the processor 200 of FIG. 2) may configure a specific location in a real space as a virtual marker. According to an embodiment, in FIG. 4, the processor 200 may identify the location 402 (or an area of a specified size) to be configured as the virtual marker, based on occurrence 400 of an event related to the virtual marker. In FIG. 4, the processor 200 may control the sensor 210 to obtain magnetic field information 404 about the location 402 (or the area of the specified size) to be configured as the virtual marker. For example, the event related to the virtual marker may occur based on at least one of execution of an application program, execution of a function, reception of a user input, or reception of a communication signal related to the virtual marker. According to an embodiment, the processor 200 may store, in the memory 240, the location 402 of the real space configured as the virtual marker, the magnetic field information 404 about the location configured as the virtual marker obtained through the sensor 210, and information related to a function related to the virtual marker. For example, the magnetic field information 404 about the location configured as the virtual marker is magnetic field information corresponding to an area of a specified size based on the location configured as the virtual marker in the real space, and may include the strength of an x-axis magnetic field, the strength of a y-axis magnetic field, and the strength of a z-axis magnetic field obtained at the same time through the sensor 210. For example, the function related to the virtual marker may include a function that is automatically executed based on the electronic device 101 being determined as having reached the location configured as the virtual marker.

According to an embodiment, in operation 303, the electronic device (e.g., the processor 120 or 200) may configure a reference distance related to a Euclidean distance, based on the magnetic field information (e.g., a change in the slopes of the magnetic fields) about the virtual marker. According to an embodiment, the processor 200 may detect the slope of the x-axis magnetic field, the slope of the y-axis magnetic field, and the slope the z-axis magnetic field of the virtual marker. For example, the slopes of the magnetic fields may be detected based on the range of a magnetic field value of each axis of the virtual mark and the slope of the magnetic field value of each axis. For example, the range of the magnetic field value may include a range between the minimum strength value and the maximum strength value of the magnetic field in each axis of the virtual mark. For example, the reference distance related to the Euclidean distance may include a reference distance configured to determine whether to perform a comparison operation for determining whether the electronic device 101 reaches the location (or area) configured as the virtual mark.

According to an embodiment, when determining that the change in the slopes of the x-axis magnetic field, the y-axis magnetic field, and the z-axis magnetic field of the virtual marker is relatively constant, the processor 200 may select a relatively short reference distance among a plurality of reference distances. For example, the processor 200 may select reference distance 2, which is relatively short, among reference distance 1 and reference distance 2 defined below in Table 1. For example, a state in which the change in the slope is constant may include a state in which the change in the slope (or slope change rate) of the x-axis magnetic field, the y-axis magnetic field, and the z-axis magnetic field is linear (or satisfies a specified linear condition).

TABLE 1

| | Reference distance 1 | Reference distance 2 |
|---|---|---|
| Allowed marker | Entire virtual marker | Part of virtual marker |
| Size | Large | Small |

According to an embodiment, when determining that the change in the slope of the x-axis magnetic field, the y-axis magnetic field, and the z-axis magnetic field of the virtual mark is not relatively constant, the processor 200 may select a relatively long reference distance among the plurality of reference distances. For example, the processor 200 may select reference distance 1, which is relatively long, among reference distance 1 and reference distance 2 defined in Table 1. For example, a state in which the change in the slope is not constant may include a state in which the change in the slope (or slope change rate) of the x-axis magnetic field, the y-axis magnetic field, and the z-axis magnetic field is nonlinear (or does not satisfy the specified linear condition).

According to an embodiment, in operation 305, the electronic device (e.g., the processor 120 or 200) may identify magnetic field information corresponding to the location of the electronic device. According to an embodiment, in FIG. 4, the processor 200 may control the sensor 210 to obtain magnetic field information about at least a portion of an area where the electronic device 101 is located, based on a specified period (or specified detection time interval) (e.g., about 100 ms) related to the virtual marker (410).

According to an embodiment, in operation 307, the electronic device (e.g., the processor 120 or 200) may detect the Euclidean distance between the virtual marker and the location of the electronic device. According to an embodiment, the processor 200 may detect the Euclidean distance, based on the magnetic field information about the location of the electronic device 101 obtained through the sensor 210 and the magnetic field information about the virtual marker. For example, the processor 200 may perform at least one of a zero mean operation or a three-axis normalization operation on at least one of the magnetic field information about the virtual marker or the magnetic field information about the location of the electronic device. The processor 200 may detect the Euclidean distance between the location of the electronic device 101 and the virtual marker, based on the magnetic field information to which at least one of the zero mean operation or the three-axis normalization operation has been applied. For example, the zero mean operation may include an operation of changing the mean of vectors included in the magnetic field information to zero (‘0’). For example, the three-axis normalization operation may include an operation of reducing the size of the vectors included in the magnetic field information. For example, the Euclidean distance is the shortest straight-line distance between the location of the electronic device 101 and the location configured as the virtual marker, and may be calculated based on the difference in the strength of a magnetic field in each axis according to Equation 1.

According to an embodiment, in operation 309, the electronic device (e.g., the processor 120 or 200) may identify whether the Euclidean distance between the location of the electronic device and the virtual marker is less than the reference distance configured based on the magnetic field information about the virtual marker. According to an embodiment, when the Euclidean distance between the location of the electronic device and the virtual marker is less than the reference distance configured based on the magnetic field information about the virtual marker, the processor 200 may determine that a specified detection condition is satisfied. According to an embodiment, when the Euclidean distance between the location of the electronic device and the virtual marker exceeds the reference distance configured based on the magnetic field information about the virtual marker, the processor 200 may determine that the specified detection condition is not satisfied.

According to an embodiment, when the Euclidean distance between the location of the electronic device and the virtual marker is equal to or greater than the reference distance configured based on the magnetic field information about the virtual marker (e.g., No in operation 309), the electronic device (e.g., the processor 120 or 200) may end the embodiment of detecting the location of the electronic device based on the virtual marker. According to an embodiment, FIG. 5 may show the relationship between the Euclidean distance between the virtual marker and the location of the electronic device 101 and the location 500 of the virtual marker. As the Euclidean distance between the virtual marker and the location of the electronic device 101 is smaller, the location of the electronic device 101 may be determined as being closer to the location 500 of the virtual marker. According to an embodiment, when the Euclidean distance between the location of the electronic device 101 and the virtual marker is equal to or greater than the reference distance configured based on the magnetic field information about the virtual marker, the processor 200 may determine that the probability that the location of the electronic device 101 reaches the location configured as the virtual marker is relatively low. The processor 200 may restrict performance of the comparison operation for determining whether the electronic device 101 reaches the location (or area) configured as the virtual marker, based on determining that the probability that the location of the electronic device 101 reaches the location configured as the virtual marker is relatively low. For example, when determining that the specified detection condition is not satisfied, the processor 200 may restrict the performance of the comparison operation for determining whether the electronic device 101 reaches the location (or area) configured as the virtual marker.

According to an embodiment, when the Euclidean distance between the location of the electronic device and the virtual marker is less than the reference distance configured based on the magnetic field information about the virtual marker (e.g., Yes in operation 309), the electronic device (e.g., the processor 120 or 200) may perform an operation of comparison between the magnetic field information about the virtual marker and the magnetic field information about the location of the electronic device in operation 311. According to an embodiment, when the Euclidean distance between the location of the electronic device 101 and the virtual marker is less than the reference distance configured based on the magnetic field information about the virtual marker, the processor 200 may determine that the probability that the location of the electronic device 101 reaches the location configured as the virtual marker is relatively high. The processor 200 may determine to perform the comparison operation for determining whether the electronic device 101 reaches the location (or area) configured as the virtual marker, based on determining that the probability that the location of the electronic device 101 reaches the location configured as the virtual marker is relatively high. For example, when determining that the specified detection condition is satisfied, the processor 200 may perform the comparison operation for determining whether the electronic device 101 reaches the location (or area) configured as the virtual marker. For example, the operation of comparison between the pieces of magnetic field information may include at least one of an operation of compensating for a change in the waveform of a signal according to the moving speed of the electronic device (e.g., a dynamic time warping (DTW) operation) or an operation of determining whether the magnetic field information about the location of the electronic device and the magnetic field information about the specific location configured as the virtual marker are similar (e.g., a correlation operation, a DTW operation, a histogram operation, a range operation, an angle operation, or a bias operation).

According to an embodiment, when determining that the electronic device 101 has reached the virtual marker through the operation of comparison between the magnetic field information about the virtual marker and the magnetic field information about the location of the electronic device (420 in FIG. 4), the electronic device 101 may execute the function related to the virtual marker.

According to an embodiment, the electronic device 101 may selectively perform an operation of comparing magnetic fields, based on the Euclidean distance from the virtual marker detected based on the pieces of magnetic field information corresponding to the virtual marker and the location of the electronic device 101, thereby reducing complexity due to the operation of comparison between the pieces of magnetic field information about the virtual marker and the location of the electronic device 101.

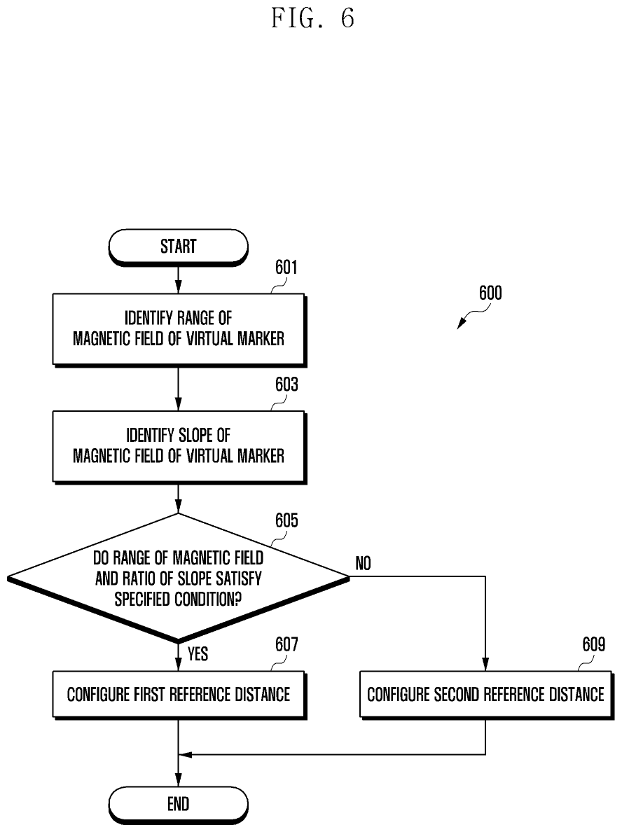

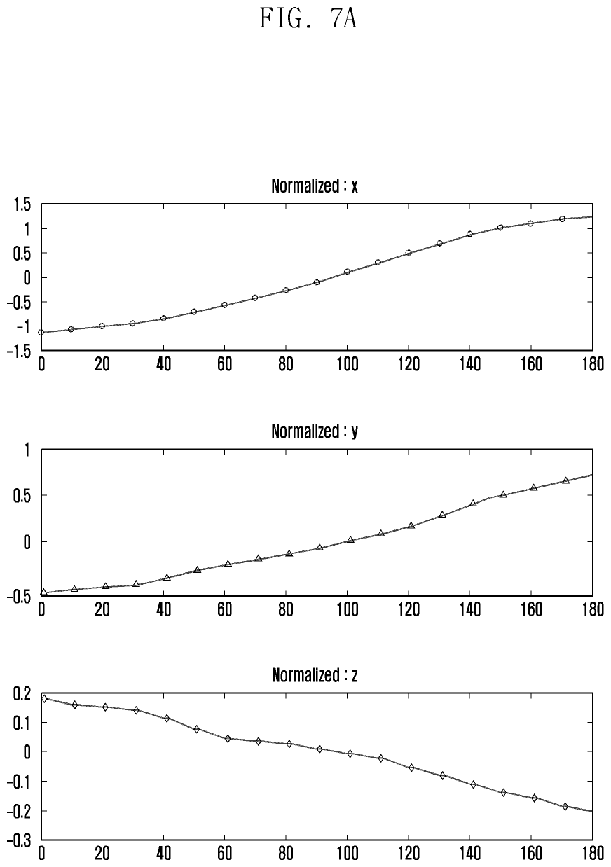

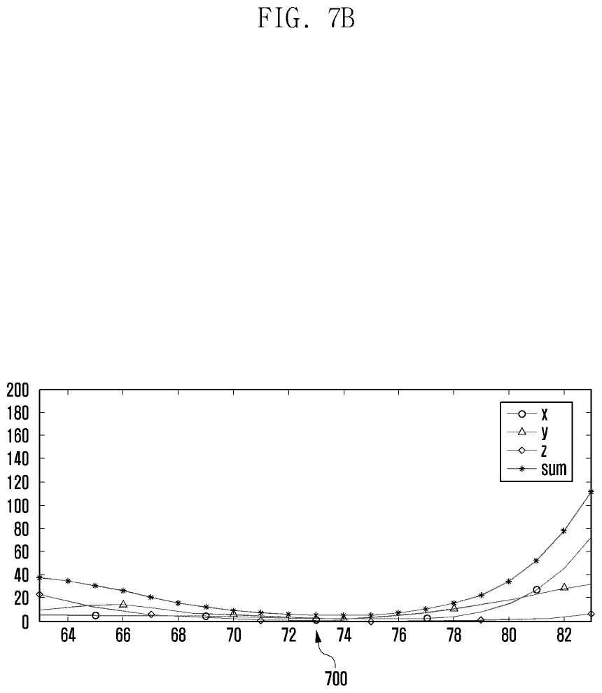

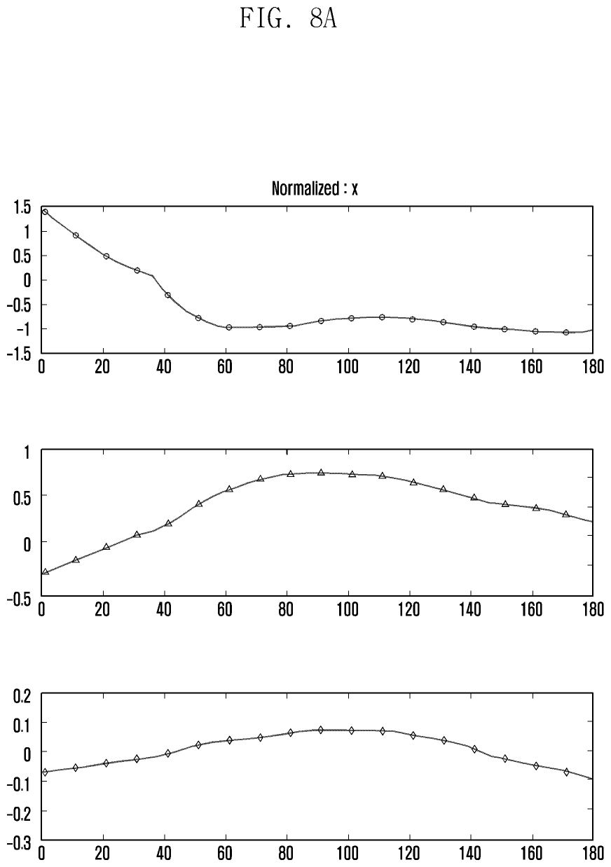

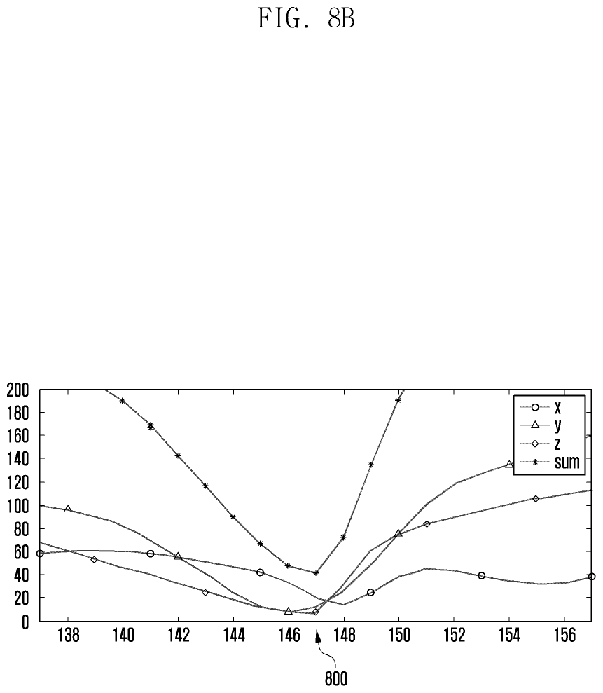

FIG. 6 is a flowchart 600 illustrating that an electronic device configures a reference distance related to a Euclidean distance according to an embodiment. According to an embodiment, at least part of FIG. 6 may include detailed operations of operation 305 of FIG. 3. In the following example, operations may be sequentially performed, but are not necessarily performed sequentially. For example, the operations may be performed in a different order, or at least two operations may be performed in parallel. For example, the electronic device of FIG. 6 may be the electronic device 101 of FIG. 1 or FIG. 2. At least part of FIG. 6 may be described with reference to FIG. 7A, FIG. 7B, FIG. 8A, and FIG. 8B. FIG. 7A illustrates an example of magnetic field information related to a virtual marker in an electronic device according to an embodiment. FIG. 7B illustrates an example of a Euclidean distance based on a virtual marker in an electronic device according to an embodiment. FIG. 8A illustrates an example of magnetic field information related to a virtual marker in an electronic device according to an embodiment. FIG. 8B illustrates an example of a Euclidean distance based on a virtual marker in an electronic device according to an embodiment.

According to an embodiment with reference to FIG. 6, FIG. 7A, FIG. 7B, FIG. 8A, and FIG. 8B, when configuring a virtual marker (e.g., operation 301 of FIG. 3), the electronic device (e.g., the processor 120 of FIG. 1 or the processor 200 of FIG. 2) may identify the range of a magnetic field of the virtual marker in operation 601. According to an embodiment, the processor 200 may perform at least one of a zero mean operation or a three-axis normalization operation on magnetic field information about the virtual marker. The processor 200 may detect the range of the magnetic field of each axis, based on the minimum value and the maximum value of magnetic field information about each axis to which at least one of the zero mean operation or the three-axis normalization operation has been applied. For example, the strength of the x-axis magnetic field (or geomagnetic value) of the virtual marker may increase from −15 to −10, the strength of the y-axis magnetic field (or geomagnetic value) may increase from 25 to 27, and the strength of the z-axis magnetic field (or geomagnetic value) may decrease from −35 to −36. The processor 200 may detect a range of the strength of the x-axis magnetic field of ‘3’ (e.g., from about −1.5 to about 1.5), a range of the strength of the y-axis magnetic field of ‘1.5’ (e.g., from about −0.5 to about 1), and a range of the strength of the z-axis magnetic field of 0.5 (e.g., from about −0.3 to about 0.2), based on the zero mean operation and the three-axis normalization operation on the magnetic field information about the virtual marker as illustrated in FIG. 7A. For example, the zero mean operation may include an operation of changing the mean of vectors included in the magnetic field information to zero (‘0’). For example, the three-axis normalization operation may include an operation of reducing the size of the vectors included in the magnetic field information.

According to an embodiment, in operation 603, the electronic device (e.g., the processor 120 or 200) may identify the slope of the magnetic fields of the virtual marker. According to an embodiment, the processor 200 may detect the slope of the division interval (e.g., about 20) of the length of the virtual marker from the strength of each of the x-axis, y-axis, and z-axis magnetic fields of the virtual marker as in Equation 2 below.

$${slope}_{j , i} = \frac{{P}_{j \times step , i} - {P}_{( j + 1 ) \times step - 1 , i}}{step} , where 0 \leq j < and step = 10 \qquad [ Equation 2 ]$$

For example, slope_{j,i} may denote the slope of a j-th division interval of an i-th axis, P_{j×step,i} may denote the range of the magnetic field (or the range of magnetic field strength) of the j-th division interval of the i-th axis of the virtual marker, i may denote the index of each axis of the magnetic field, j may denote the index of the division interval, and step may denote the size of the division interval.

For example, the processor 200 may detect the range of the slope of the i-th axis of the virtual marker by using Equation 2 as in Equation 3. For example, the range of the slope (range of slope;) of the i-th axis of the virtual marker may be calculated based on the difference between the maximum slope and the minimum slope of the division interval.

$$range of {slope}_{i} = max ( {slope}_{0 , i} , {slope}_{1 , i} , … , {slope}_{\frac{M}{slope} - 1 , i} ) - min ( {slope}_{0 , i} , {slope}_{1 , i} , … , {slope}_{\frac{M}{slope} - 1 , i} ) \qquad [ Equation 3 ]$$

According to an embodiment, in operation 605, the electronic device (e.g., the processor 120 or 200) may identify whether the range and slope of the magnetic fields of the virtual marker satisfy a specified condition (or a specified linear condition). According to an embodiment, the processor 200 may calculate the sum of ratios of the slope of the magnetic fields of the x-axis, y-axis, and z-axis of the virtual marker to the range of the magnetic fields as in Equation 4 below.

$${\sum }_{i = 0}^{2} \frac{range of {slope}_{i}}{{range}_{i}} \qquad [ Equation 4 ]$$

According to an embodiment, when the result of Equation 4 is less than a specified reference value of the virtual mark, the processor 200 may determine that the specified condition is satisfied. For example, a state in which the result of Equation 4 is less than the specified reference value of the virtual mark (or a state in which the specified condition is satisfied) may indicate a state in which a change in the slope (or slope change rate) of the x-axis magnetic field, the y-axis magnetic field, and the z-axis magnetic field of the virtual marker is linear as in FIG. 7A.

According to an embodiment, when the result of Equation 4 is equal to or greater than the specified reference value of the virtual mark, the processor 200 may determine that the specified condition is not satisfied. For example, a state in which the result of Equation 4 is equal to or greater than the specified reference value of the virtual mark (or a state in which the specified condition is not satisfied) may indicate a state in which a change in the slope (or slope change rate) of the x-axis magnetic field, the y-axis magnetic field, and the z-axis magnetic field of the virtual marker is nonlinear as in FIG. 8A.

According to an embodiment, when the range and slope of the magnetic fields of the virtual marker satisfy the specified condition (e.g., Yes in operation 605), the electronic device (e.g., the processor 120 or 200) may configure a relatively short first reference distance among a plurality of specified reference distances as a reference distance for determining whether to perform a comparison operation related to detection of the virtual marker in operation 607. According to an embodiment, the Euclidean distance between the virtual marker and the electronic device 101 may be maintained relatively low with respect to the virtual marker 700 as shown in FIG. 7B when the change in the slope of the x-axis magnetic field, the y-axis magnetic field, and the z-axis magnetic field of the virtual marker is determined as being relatively constant as shown in FIG. 7A. When the range and slope of the magnetic fields of the virtual marker satisfy the specified condition, the Euclidean distance between the virtual marker and the electronic device 101 is maintained relatively low with respect to the virtual marker 700 as shown in FIG. 7B, and thus the processor 200 may configure a relatively short reference distance. For example, the processor 200 may select a relatively short reference distance (e.g., reference distance 2 in Table 1) among the plurality of reference distances. For example, the Euclidean distance between the virtual marker and the electronic device 101 may be detected based on the magnetic field information about the virtual marker and magnetic field information corresponding to the location of the electronic device 101 according to Equation 1.

According to an embodiment, when the range and slope of the magnetic fields of the virtual marker do not satisfy the specified condition (e.g., No in operation 605), the electronic device (e.g., the processor 120 or 200) may configure a relatively long second reference distance among the plurality of specified reference distances as the reference distance for determining whether to perform the comparison operation related to the detection of the virtual marker in operation 609. According to an embodiment, the Euclidean distance between the virtual marker and the electronic device 101 may relatively significantly change with respect to the virtual marker 700 as shown in FIG. 8B when the change in the slope of the x-axis magnetic field, the y-axis magnetic field, and the z-axis magnetic field of the virtual marker is determined as not being relatively constant as shown in FIG. 8A. When the range and slope of the magnetic fields of the virtual marker do not satisfy the specified condition, the Euclidean distance between the virtual marker and the electronic device 101 relatively significantly changes with respect to the virtual marker 700 as shown in FIG. 8B, and thus the processor 200 may configure a relatively long reference distance. For example, the processor 200 may select a relatively long reference distance (e.g., reference distance 1 in Table 1) among the plurality of reference distances.

According to an embodiment, an operating method of an electronic device (e.g., the electronic device 101 of FIG. 1 or FIG. 2) may include obtaining information about a first magnetic field of a virtual marker through a sensor (e.g., the sensor module 176 of FIG. 1 or the sensor 210 of FIG. 2). According to an embodiment, the operating method of the electronic device may include configuring a reference distance, based on the information about the first magnetic field of the virtual marker. According to an embodiment, the operating method of the electronic device may include obtaining information about a second magnetic field corresponding to a location of the electronic device, based on a specified detection time interval. According to an embodiment, the operating method of the electronic device may include detecting a Euclidean distance, based on the information about the first magnetic field of the virtual marker and the information about the second magnetic field corresponding to the location of the electronic device. According to an embodiment, the operating method of the electronic device may include restricting an operation of comparison between the information about the first magnetic field and the information about the second magnetic field when the Euclidean distance based on the information about the first magnetic field of the virtual marker and the information about the second magnetic field corresponding to the location of the electronic device does not satisfy a specified detection condition based on the reference distance. According to an embodiment, the operating method of the electronic device may include performing the operation of comparison between the information about the first magnetic field and the information about the second magnetic field when the Euclidean distance based on the information about the first magnetic field of the virtual marker and the information about the second magnetic field corresponding to the location of the electronic device satisfies the specified detection condition based on the reference distance.

According to an embodiment, the configuring of the reference distance may include selecting one of a plurality of specified reference distances having different distances, based on the range of the first magnetic field of the virtual marker and the slope of the first magnetic field.

According to an embodiment, the selecting of the reference distance may include detecting a change rate of the slope of the first magnetic field, based on the range of the first magnetic field of the virtual marker and the slope of the first magnetic field, selecting one relatively short reference distance among the plurality of reference distances when the change rate of the slope of the first magnetic field satisfies a specified linear condition, and selecting another relatively long reference distance among the plurality of reference distances when the change rate of the slope of the first magnetic field does not satisfy the specified linear condition.

According to an embodiment, the detecting of the Euclidean distance may include detecting the Euclidean distance between the virtual marker and the location of the electronic device, based on a difference in strength between a magnetic field of each of three axes related to the virtual marker and a magnetic field of each of the three axes corresponding to the location of the electronic device.

According to an embodiment, the restricting of the operation of comparison may include restricting the operation of comparison between the information about the first magnetic field of the virtual marker and the information about the second magnetic field of the location of the electronic device when the Euclidean distance between the virtual marker and the electronic device exceeds the reference distance.

According to an embodiment, the restricting of the operation of comparison may include performing the operation of comparison between the information about the first magnetic field of the virtual marker and the information about the second magnetic field of the location of the electronic device when the Euclidean distance between the virtual marker and the electronic device is less than or equal to the reference distance.

According to an embodiment, the operation of comparison between the first magnetic field of the virtual marker and the second magnetic field of the location of the electronic device may include at least one of a dynamic time warping (DTW) operation, a correlation operation, a histogram operation, a range operation, an angle operation, or a bias operation.

According to an embodiment, the operating method of the electronic device may include storing information related to at least one of a location of a real space configured as the virtual marker based on obtaining the information about the first magnetic field of the virtual marker, the information about the first magnetic field obtained through the sensor of the electronic device, or a function related to the virtual marker.

According to an embodiment, the operating method of the electronic device may include automatically executing the function related to the virtual marker when determining that the electronic device reaches the virtual marker through the operation of comparison between the first magnetic field of the virtual marker and the second magnetic field of the location of the electronic device.

According to an embodiment of the disclosure, an electronic device may selectively perform an operation of comparing magnetic field information about a location configured as a virtual marker and magnetic field information about the location of the electronic device, based on a Euclidean distance (or dot product) detected based on the magnetic field information about the location configured as the virtual marker and the magnetic field information about the location of the electronic device, thereby reducing at least one of complexity in an operation of detecting the location of the electronic device based on the virtual marker, the load of a processor, or power consumption.

Embodiments of the disclosure disclosed in the specification and drawings are provided as specific examples to easily explain technical content according to the embodiments of the disclosure and to facilitate understanding of the embodiments of the disclosure, and are not intended to limit the scope of the embodiments of the disclosure. Accordingly, the scope of embodiments of the disclosure should be construed as including all changes or modifications derived based on the technical idea of embodiments of the disclosure in addition to the embodiments disclosed herein.

What is claimed is:

1. An electronic device comprising:
a sensor;
memory storing instructions; and
at least one processor operatively connected to the sensor,
wherein the instructions which, when executed by the at least one processor individually or collectively, cause the electronic device to:
obtain information about a first magnetic field of a virtual marker through the sensor;
configure a reference distance, based on the information about the first magnetic field of the virtual marker;
obtain information about a second magnetic field corresponding to a location of the electronic device, based on a specified detection time interval;
detect a Euclidean distance, based on the information about the first magnetic field of the virtual marker and the information about the second magnetic field corresponding to the location of the electronic device;
restrict an operation of comparing the information about the first magnetic field and the information about the second magnetic field in a state in which the Euclidean distance does not satisfy a specified detection condition based on the reference distance; and
perform the operation of comparing the information about the first magnetic field and the information about the second magnetic field in a state in which the Euclidean distance satisfies the specified detection condition based on the reference distance.

2. The electronic device of claim 1, wherein the instructions which, when executed by the at least one processor individually or collectively, cause the electronic device to obtain information about a magnetic field in three axes related to at least a portion of a real space configured as the virtual marker through the sensor.

3. The electronic device of claim 1, wherein the instructions which, when executed by the at least one processor individually or collectively, cause the electronic device to:
detect a range of the first magnetic field and a slope of the first magnetic field; and
select one of a plurality of specified reference distances having different distances, based on the range of the first magnetic field and the slope of the first magnetic field.

4. The electronic device of claim 3, wherein the instructions which, when executed by the at least one processor individually or collectively, cause the electronic device to:
detect a change rate of the slope of the first magnetic field, based on the range of the first magnetic field and the slope of the first magnetic field;
select a shortest reference distance among the plurality of reference distances in a state in which the change rate of the slope of the first magnetic field satisfies a specified linear condition; and
select a longest reference distance among the plurality of reference distances in a state in which the change rate of the slope of the first magnetic field does not satisfy the specified linear condition.

5. The electronic device of claim 1, wherein the instructions which, when executed by the at least one processor individually or collectively, cause the electronic device to detect the Euclidean distance between the virtual marker and the location of the electronic device, based on a difference in strength between a magnetic field in each of three axes related to the virtual marker and a magnetic field in each of the three axes corresponding to the location of the electronic device.

6. The electronic device of claim 5, wherein the instructions which, when executed by the at least one processor individually or collectively, cause the electronic device to:
restrict the operation of comparing the information about the first magnetic field and the information about the second magnetic field in a state in which the Euclidean distance exceeds the reference distance; and
perform the operation comparing the information about the first magnetic field and the information about the second magnetic field in a state in which the Euclidean distance is less than or equal to the reference distance.

7. The electronic device of claim 1, wherein the memory is further configured to store information related to at least one of a location of a real space configured as the virtual marker, the information about the first magnetic field obtained through the sensor, or a function related to the virtual marker.

8. The electronic device of claim 1, wherein the memory storing instructions which, when executed by the at least one processor individually or collectively, cause the electronic device to automatically execute a function related to the virtual marker stored in the at least one memory based on determining that the electronic device reaches the virtual marker through the operation of comparing.

9. The electronic device of claim 1, wherein the operation of comparing the information about the first magnetic field and the information about the second magnetic field includes at least one of a dynamic time warping (DTW) operation, a correlation operation, a histogram operation, a range operation, an angle operation, or a bias operation.

10. An operating method of an electronic device, the method comprising:
obtaining information about a first magnetic field of a virtual marker through a sensor of the electronic device;
configuring a reference distance, based on the information about the first magnetic field of the virtual marker;
obtaining information about a second magnetic field corresponding to a location of the electronic device, based on a specified detection time interval;
detecting a Euclidean distance, based on the information about the first magnetic field of the virtual marker and the information about the second magnetic field corresponding to the location of the electronic device;
restricting an operation of comparing the information about the first magnetic field and the information about the second magnetic field in a state in which the Euclidean distance does not satisfy a specified detection condition based on the reference distance; and
performing the operation of comparing the information about the first magnetic field and the information about the second magnetic field in a state in which the Euclidean distance satisfies the specified detection condition based on the reference distance.

11. The method of claim 10, wherein the configuring the reference distance comprises:
detecting a range of the first magnetic field and a slope of the first magnetic field; and
selecting one of a plurality of specified reference distances having different distances, based on the range of the first magnetic field and the slope of the first magnetic field.

12. The method of claim 11, wherein the selecting the reference distance comprises:
detecting a change rate of the slope of the first magnetic field, based on the range of the first magnetic field and the slope of the first magnetic field;
selecting a shortest reference distance among the plurality of reference distances in a state in which the change rate of the slope of the first magnetic field satisfies a specified linear condition; and
selecting a longest reference distance among the plurality of reference distances in a state in which the change rate of the slope of the first magnetic field does not satisfy the specified linear condition.

13. The method of claim 10, wherein the detecting the Euclidean distance comprises detecting the Euclidean distance between the virtual marker and the location of the electronic device, based on a difference in strength between a magnetic field in each of three axes related to the virtual marker and a magnetic field in each of the three axes corresponding to the location of the electronic device.

14. The method of claim 10, wherein the restricting the operation of comparing comprises restricting the operation of comparing the information about the first magnetic field and the information about the second magnetic field in a state in which the Euclidean distance exceeds the reference distance.

15. The method of claim 10, wherein the performing the operation of comparing comprises performing the operation of comparing the information about the first magnetic field and the information about the second magnetic field in a state in which the Euclidean distance is less than or equal to the reference distance.

16. The method of claim 10, further comprising automatically executing a function related to the virtual marker based on determining that the electronic device reaches the virtual marker through the operation of comparing.

17. The method of claim 10, wherein the operation of comparing the information about the first magnetic field and the information about the second magnetic field includes at least one of a dynamic time warping (DTW) operation, a correlation operation, a histogram operation, a range operation, an angle operation, or a bias operation.

18. A non-transitory computer-readable storage medium for storing one or more programs comprising computer-executable instructions that, when individually or collectively executed by at least one processor of an electronic device, cause the electronic device to:
obtain information about a first magnetic field of a virtual marker through the sensor;
configure a reference distance, based on the information about the first magnetic field of the virtual marker;
obtain information about a second magnetic field corresponding to a location of the electronic device, based on a specified detection time interval;
detect a Euclidean distance, based on the information about the first magnetic field of the virtual marker and the information about the second magnetic field corresponding to the location of the electronic device;
restrict an operation of comparing the information about the first magnetic field and the information about the second magnetic field in a state in which the Euclidean distance does not satisfy a specified detection condition based on the reference distance; and
perform the operation of comparing the information about the first magnetic field and the information about the second magnetic field in a state in which the Euclidean distance satisfies the specified detection condition based on the reference distance.

19. The non-transitory computer-readable storage medium of claim 18, wherein the one or more programs comprising computer-executable instructions that, when individually or collectively executed by at least one processor of an electronic device, cause the electronic device to:
detect a range of the first magnetic field and a slope of the first magnetic field; and
select one of a plurality of specified reference distances having different distances, based on the range of the first magnetic field and the slope of the first magnetic field.

20. The non-transitory computer-readable storage medium of claim 19, wherein the one or more programs comprising computer-executable instructions that, when individually or collectively executed by at least one processor of an electronic device, cause the electronic device to:
detect a change rate of the slope of the first magnetic field, based on the range of the first magnetic field and the slope of the first magnetic field;
select a shortest reference distance among the plurality of reference distances in a state in which the change rate of the slope of the first magnetic field satisfies a specified linear condition; and
select a longest reference distance among the plurality of reference distances in a state in which the change rate of the slope of the first magnetic field does not satisfy the specified linear condition.
